(19) United States
(12) Patent Application Publication
(10) Pub. No.: US 2024/0217203 A1
(43) Pub. Date: Jul. 4, 2024

(54) Support Plate, Method for Manufacturing the Same and Foldable Display Device Comprising the Same

(71) Applicant: LG Display Co., Ltd., Seoul (KR)

(72) Inventors: Jieun Lee, Seoul (KR); Heeyeon Hwang, Paju-si (KR); SangHoon Oh, Jeollabuk-do (KR); SoJung Park, Daegu (KR); Minwan Kim, Paju-si (KR)

(21) Appl. No.: 18/467,654

(22) Filed: Sep. 14, 2023

(30) Foreign Application Priority Data
Dec. 29, 2022 (KR) 10-2022-0189134

(51) Int. Cl. B32B 5/12; B32B 27/12; B32B 37/18; B32B 38/00; B32B 38/08; B32B 38/18; H05K 5/02

(52) U.S. Cl. CPC B32B 5/12; B32B 27/12; B32B 37/185; B32B 38/0004; B32B 38/0012; B32B 38/08; B32B 38/1808; H05K 5/02; B32B 2260/023; B32B 2260/046; B32B 2262/106; B32B 2305/076; B32B 2305/74; B32B 2307/54; B32B 2307/7376; B32B 2313/04; B32B 2457/20

(57) ABSTRACT

A support plate, a method of manufacturing the same, and a foldable display device including the same. The support plate is provided on a bottom portion of a back plate bendable about a folding axis. The support plate includes a support layer. The support layer includes one or more prepregs each comprising a resin and carbon fibers. The support plate is provided in a semi-cured state, and is attached to the bottom portion of the back plate without an adhesive. The support plate is enabled to be folded without an open area pattern.

### CROSS REFERENCE TO RELATED APPLICATION

This application claims priority from Korean Patent Application No. 10-2022-0189134, filed on Dec. 29, 2022, which is hereby incorporated by reference for all purposes as if fully set forth herein.

### BACKGROUND

### Field

Embodiments relate to a support plate, a method of manufacturing the same, and a foldable display device including the same.

### Description of Related Art

Recently, upon the advent of the information age, the field of displays for visually expressing electrical information signals has developed rapidly. In response to this, various display devices having excellent characteristics, such as a thin profile, a light weight, and low power consumption, are being developed. Specific examples of such display devices may include a liquid crystal display (LCD), a plasma display panel (PDP), a field emission display (FED), an organic light-emitting diode (OLED) display, and the like.

Recently, flexible display devices manufactured using a flexible material such as a plastic substrate instead of a conventional inflexible material, such as a glass substrate, so as to maintain display performance even when a state of being folded or bent like a sheet of paper are rapidly emerging as next-generation display devices.

Flexible display devices use a thin film transistor (TFT) substrate of plastic instead of glass, and may be categorized as an unbreakable display device with high durability, a bendable display device that can be folded without being broken, a rollable display device that can be rolled, a foldable display device that can be folded, and the like. Flexible display devices may be advantageous in association with space utilization, interior design, and design, and may be used in various fields of application.

In particular, in order to realize a large area characteristic along with ultra-thin profile, a light weight, and miniaturization characteristics, research into a foldable display device that can be carried in a folded state and display images in an unfolded state is being actively undertaken.

Such foldable display devices may be used not only in mobile devices, such as a mobile phone, an ultra-mobile personal computer (PC), an electronic book, and an electronic newspaper, but also in a variety of other fields, such as a TV and a monitor.

FIG. 1 is a cross-sectional diagram illustrating a foldable display device of the related art.

Referring to FIG. 1, a foldable display device 1 may include a display panel 11 including a folding area FA and non-folding areas NFA; a back plate 12 disposed on the bottom of the display panel 11 to support the display panel 11; a plate bottom portion 13 disposed in a lowermost position of the display panel 11 and having an open area pattern of a plurality of open areas in positions corresponding to the folding area to enable the display panel 11 and thus the foldable display device 1 to be foldable; a plate top portion 14 disposed between the back plate 12 and the plate bottom portion 13 to prevent the open area pattern from being visible; a first adhesion layer 15 bonding the back plate 12 and the plate top portion 14; and a second adhesion layer 16 bonding the plate top portion 14 and the plate bottom portion 13.

In addition, the first adhesion layer 15 and the second adhesion layer 16 used in the foldable display device may have low moduli in order not to limit the flexibility of the foldable display device 1. Due to this characteristic, when the foldable display device 1 is folded, the first adhesion layer 15 and the second adhesion layer 16 are pressed by members located thereabove, and significant deformations may occur from the folding area FA toward the non-folding areas NFA.

When deformations occur in the folding area FA due to the pressing, the thicknesses of the first adhesion layer 15 and the second adhesion layer 16 located in the folding area FA may be reduced, and thus the open area pattern of the plate bottom portion 13 may be visible in the display panel 11.

### BRIEF SUMMARY

In this regard, the inventors of this specification have invented a support plate, a method of manufacturing the same, and a foldable display device including the same, in which the support plate and the foldable display device may be enabled to be foldable even without a plate bottom portion in which an open area pattern is formed.

Embodiments may provide a support plate, a method of manufacturing the same, and a foldable display device including the same, in which the foldable display device may be enabled to be foldable only using a single support plate without an open area pattern provided in the lower portion of a back plate in order to overcome the problem that the pattern is visible in the display panel.

Embodiments may provide a support plate, a method of manufacturing the same, and a foldable display device including the same, in which the structure of the lower portion of the back plate may be simplified in order to simplify a fabrication process and a supply chain management (SCM), increase production yield, and reduce fabrication costs.

Embodiments may provide a support plate for a foldable display device. The support plate may be provided on a bottom portion of a back plate bendable about a folding axis. The support plate may include a support layer. The support layer may include one or more prepregs each comprising a resin and carbon fibers. The support plate may have a semi-cured state when being attached to the bottom portion of the back plate.

Embodiments may provide a method of manufacturing a support plate for a foldable display device. The method may include: preparing a semi-cured prepreg including a resin and carbon fibers oriented in a single direction; and manufacturing a support layer by stacking the one or more prepregs.

Embodiments may provide a foldable display device including: a display panel including a folding area and a non-folding area; a back plate supporting a bottom portion of the display panel; and a support plate supporting a bottom portion of the back plate, and including one or more prepregs each including a resin and carbon fibers. The support plate may have a semi-cured state when being attached to the bottom portion of the back plate.

In the support plate, the method of manufacturing the same, and the foldable display device including the same according to embodiments, the problem that the pattern is visible in the display panel may be overcome by only providing the lower portion of the back plate with the single support plate that is foldable and enables the foldable display device to be foldable without the open area pattern.

In the support plate, the method of manufacturing the same, and the foldable display device including the same according to embodiments, the fabrication process and the supply chain management (SCM) may be simplified, the production yield may be increased, and fabrication costs may be reduced by simplifying the structure of the lower portion of the back plate.

In the support plate, the method of manufacturing the same, and the foldable display device including the same according to embodiments, the support plate may be formed of a uni-material such that the structure of the lower portion of the back plate may be simplified and unified.

### DESCRIPTION OF DRAWINGS

The above and other objectives, features, and advantages of the present disclosure will be more clearly understood from the following detailed description, taken in conjunction with the accompanying drawings, in which:

FIG. 1 is a cross-sectional diagram illustrating a foldable display device of the related art;

FIG. 2 is a cross-sectional diagram illustrating a foldable display device according to embodiments;

FIG. 3 is a perspective diagram schematically illustrating a support plate of the foldable display device illustrated in FIG. 2;

FIG. 4 is a diagram schematically illustrating examples in which the prepregs of the support layer are stacked;

FIG. 5 is a perspective diagram illustrating a support layer according to an embodiment;

FIG. 6 is a perspective diagram illustrating a support layer according to another embodiment;

FIG. 7 is a graph illustrating the tensile strengths of the support layers and related folding test results according to the example illustrated in Table 1;

FIG. 8 is a graph illustrating tensile strength and resilience according to the ratio of the second prepreg included in the support layer illustrated in FIG. 6;

FIG. 9 is a graph illustrating the thickness uniformity and tackiness of the support layer according to the resin content in the prepreg;

FIG. 10 is a flowchart illustrating a method of manufacturing a support plate for a foldable display device according to an embodiment;

FIG. 11 is a conceptual diagram schematically illustrating a prepreg preparing process according to an embodiment;

FIG. 12 is a conceptual diagram schematically illustrating a support layer manufacturing process according to an embodiment;

FIG. 13 is a conceptual diagram schematically illustrating a support layer manufacturing process according to another embodiment; and

FIG. 14 is a conceptual diagram schematically illustrating a support layer attachment process according to an embodiment.

### DETAILED DESCRIPTION

In the following description of examples or embodiments of the present invention, reference r will be made to the accompanying drawings in which it is shown by way of illustration specific examples or embodiments that can be implemented, and in which the same reference numerals and signs can be used to designate the same or like components even when they are shown in different accompanying drawings from one another. Further, in the following description of examples or embodiments of the present invention, detailed descriptions of well-known functions and components incorporated herein will be omitted when it is determined that the description may make the subject matter in some embodiments of the present invention rather unclear. The terms such as “including”, “having”, “containing”, “constituting” “made up of”, and “formed of” used herein are generally intended to allow other components to be added unless the terms are used with the term “only”. As used herein, singular forms are intended to include plural forms unless the context clearly indicates otherwise.

Terms, such as “first”, “second”, “A”, “B”, “(A)”, or “(B)” may be used herein to describe elements of the present invention. Each of these terms is not used to define essence, order, sequence, or number of elements etc., but is used merely to distinguish the corresponding element from other elements.

When it is mentioned that a first element “is connected or coupled to”, “contacts or overlaps” etc. a second element, it should be interpreted that, not only can the first element “be directly connected or coupled to” or “directly contact or overlap” the second element, but a third element can also be “interposed” between the first and second elements, or the first and second elements can “be connected or coupled to”, “contact or overlap”, etc. each other via a fourth element. Here, the second element may be included in at least one of two or more elements that “are connected or coupled to”, “contact or overlap”, etc. each other.

When time relative terms, such as “after”, “subsequent to”, “next”, “before”, and the like, are used to describe processes or operations of elements or configurations, or flows or steps in operating, processing, manufacturing methods, these terms may be used to describe non-consecutive or non-sequential processes or operations unless the term “directly” or “immediately” is used together.

In addition, when any dimensions, relative sizes etc. are mentioned, it should be considered that numerical values for an elements or features, or corresponding information (e.g., level, range, etc.) include a tolerance or error range that may be caused by various factors (e.g., process factors, internal or external impacts, noise, etc.) even when a relevant description is not specified. Further, the term “may” fully encompass all the meanings of the term “can”.

Hereinafter, a variety of embodiments will be described in detail with reference to the accompanying drawings.

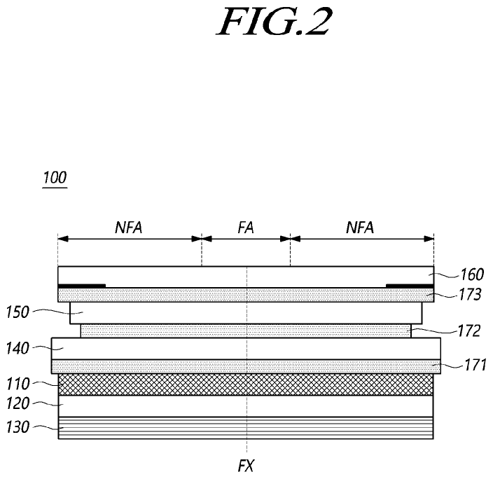

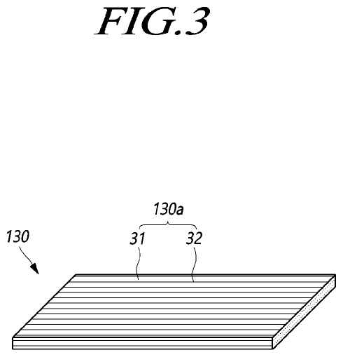

FIG. 2 is a cross-sectional diagram illustrating a foldable display device according to embodiments, and FIG. 3 is a perspective diagram schematically illustrating a support plate of the foldable display device illustrated in FIG. 2.

Referring to FIGS. 2 and 3, a foldable display device 100 may include a display panel 110, a back plate 120, and a support plate 130.

Hereinafter, in the following embodiments, for convenience of description, the back plate 120 and the support plate 130 will be described as being located on the rear surface of the display panel 110, i.e., in the lower portion in the figures, on the assumption that a display surface of the display panel 110 on which images are displayed faces toward the front.

The display panel 110 is a panel on which images are displayed. Light-emitting elements for realizing images, as well as circuits, conductive lines, components, and the like for driving the light-emitting elements, may be disposed in the display panel 110. For example, the display panel 110 may be one selected from among a liquid crystal display (LCD) device, a field-emission display (FED) device, an electroluminescence display (ELD) device, an organic light-emitting diode (OLED) display device, an inorganic light-emitting display device, and the like. In embodiments, the display device may be implemented using an OLED display device that is representative of a flexible display device able to maintain display performance even in a state of being folded like a sheet of paper.

The OLED display device is a self-luminous display device that does not require a backlight used in an LCD that does not emit light by itself, and thus may be lightweight and thin. In addition, the OLED display device has a variety of merits such as a superior viewing angle and contrast ratio compared to those of the LCD, advantageous power consumption, drivability at a low DC voltage, a high response rate, robustness to external impacts due to solid internal components, and a wide temperature range. In particular, the fabrication cost of the OLED display device may be significantly reduced, as compared to the LCD, due to a simple fabrication process.

The display panel 110 may include a folding area FA and

non-folding areas NFA.

The folding area FA is an area in which the flexible display device 100 may be folded, i.e., bent. The folding area FA may be folded about a folding axis FX and at a specific curvature radius.

Although the folding axis FX is illustrated as being disposed at the center of the display panel 110 in FIG. 2, the position and number of the folding axes FX may be variously modified. In addition, the folding area FA may be variously modified depending on the position and number of the folding axes FX but is not limited thereto.

The non-folding areas NFA are areas in which the display panel 110 is not folded and maintains a flat state. For example, the non-folding areas NFA may extend from the folding area FA in opposite directions. Two non-folding areas NFA may be disposed on both edges of the folding area FA.

When the flexible display device 100 is in an unfolded state, the folding area FA and the non-folding areas NFA may be coplanar. In addition, when the flexible display device 100 is folded about the folding axis FX, the non-folding areas NFA on both edges of the folding area FA may be disposed to face each other while remaining flat.

A polarizer layer 140, a cover glass 150, and a cover window 160 may be sequentially stacked on the front surface of the display panel 110, i.e., above the display panel 110 in the figure.

The polarizer layer 140 is configured to reduce the reflection of external light striking the display panel 110 by selectively allowing light to pass therethrough. The polarizer layer 140 may be attached to the top portion of the display panel 110 by means of a first adhesion layer 171. For example, the polarization layer 140 may be formed of polyvinyl alcohol (PVA), polycarbonate (PC), poly (methyl methacrylate) (PMMA), or the like. The first adhesion layer 171 may be implemented using an optical clear adhesive (OCA) having superior adhesiveness while allowing 97% or more light to pass therethrough.

The cover glass 150 is configured to protect the display panel 110. The cover glass 150 may be attached to the top portion of the polarizer layer 140 by means of a second adhesion layer 172 formed of an OCA.

The cover glass 150 may be formed of a glass material having superior strength and impact resistance and high surface hardness while having superior optical properties. For example, the cover glass may be a thin cover glass (TCG) having a thickness of 90 μm or lower. The thin cover glass having a limited thickness as above may effectively reduce stress applied when the display device is being folded or bent.

The cover window 160 is configured to protect the display device from external impacts and scratches. The cover window 160 may be attached to the top portion of the cover glass 150 by means of a third adhesion layer 173 formed of an OCA.

The cover window 160 may be formed of a material having superior impact resistance and scratch resistance while being transparent. For example, the cover window 160 may be implemented using a polymer film by which the folding ability may be realized. In an example, the polymer film may be a film including a polymer such as polyimide, polyamide-imide, polyethylene terephthalate, polymethyl methacrylate, polypropylene glycol, or polycarbonate. In another example, the polymer film may be formed of a photoisotropic polymer such as cyclo olefin (co) polymer, photoisotropic polycarbonate, or photoisotropic polymethyl methacrylate.

The back plate 120 is configured to prevent sagging due to the low thickness of the display panel 110 and compensate for the strength of the display panel 110. The back plate 120 may support the bottom portion of the display panel 110. As the back plate 120 is provided on the bottom portion of the display panel 110 in this manner, the back plate 120 may also be folded about the folding axis FX.

The back plate 120 may be formed of a polymer material to enabling the folding. For example, the back plate 120 may be formed of a polymer material such as poly (methyl methacrylate) (PMMA), polycarbonate (PC), polyvinyl alcohol (PVA), acrylonitrile butadiene-styrene (ABS), polyethylene terephthalate (PET), silicone, or polyurethane (PU).

The support plate 130 is configured to enable the display panel 110 to be foldable. The support plate 130 may be provided on the bottom portion of the back plate 120. The support plate 130 may include a support layer 130 on which one or more prepregs 130a respectively including a resin 31 and carbon fibers 32 are stacked. For example, the support layer 130 may include a single prepreg 130a or may be formed by stacking two or more prepregs 130a.

The resin 31 of the prepreg 130a may be a thermosetting resin having superior mechanical properties and superior heat resistance. For example, the thermosetting resin may be an epoxy resin, for example, a bisphenol-type epoxy resin, such as a bisphenol-A type epoxy resin, a bisphenol-F type epoxy resin, or a bisphenol-S type epoxy resin, or a novolac-type epoxy resin, such as a phenol novolac-type epoxy resin or a cresol novolac-type epoxy resin.

A curing agent may be used in an epoxy resin composition. The curing agent may be implemented as any compound having an active group capable of reacting with an epoxy group. For example, the curing agent may be a compound having an amino group, an acid anhydride group, or an azide group.

The carbon fibers 32 of the prepreg 130a may be formed of a carbon fiber reinforced plastic (CFRP), and may be oriented in a single direction. That is, the prepreg 130a may be a unidirectional (UD) prepreg in which the carbon fibers 32 are oriented in a single direction.

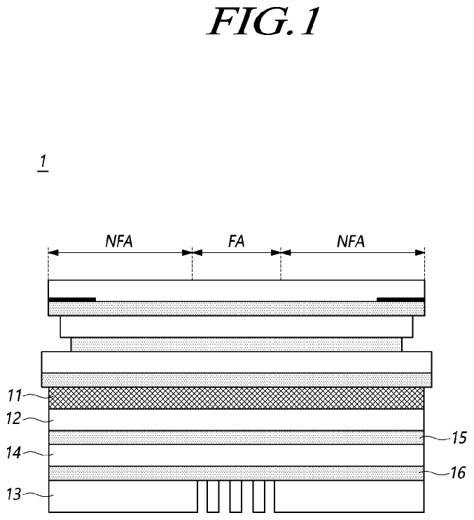

When the support plate 130 is implemented using a UD prepreg in this manner, the display panel 110 may be enabled to be foldable in an intended direction on the basis of the direction of the carbon fibers 32 included inside the UD prepreg. That is, in the related art, as illustrated in FIG. 1, the folding ability was provided using the plate bottom portion 13 having the open area pattern. However, according to embodiments, the folding ability may be enabled using the orientation of the carbon fibers 32 of the support plate 130 without using the open area pattern. Accordingly, a process for forming the open area pattern may be omitted, and the problem that the open area pattern is transferred to and visible on the display panel 110 may be overcome.

In addition, in the related art, in order to prevent the open area pattern from being visible from above the plate bottom portion 13, the plate top portion 14 and the second adhesion layer 16 for attaching the plate top portion 14 to the plate bottom portion 13 are required to be provided above the plate bottom portion 13. In contrast, according to embodiments, the support plate 130 enabling the display panel 110 to be foldable is not provided with an open area pattern. The plate bottom portion 13, the plate top portion 14, and the second adhesion layer 16 located below the back plate 12 may be omitted.

Accordingly, fabrication costs may be reduced, and production yield may be increased. In addition, by removing the layers provided below the back plate 120, the foldable display device 100 having a light weight and a thin profile may be fabricated. In addition, since the overall thickness of the display panel 110 may be reduced, the folding area FA may be more smoothly and properly folded, thereby optimizing the structure of the foldable OLED display device.

The support plate 130 may be provided in a semi-cured state and attached to the bottom portion of the back plate 120. As the support plate 130 is provided in the semi-cured state, the support plate 130 may be attached to the bottom portion of the back plate 120 without an adhesive material such as an OCA. Thus, in a process of fabricating the foldable display device 100, an operation of applying an adhesive to the bottom portion of the back plate 120 may be omitted, thereby reducing fabrication costs and process times.

The support layer 130 according to embodiments may include a plurality of prepregs 130a stacked on each other. The thickness of the support layer 130 in which a plurality of prepregs 130a are stacked may be in the range of 70 μm to 90 μm. This is because when the thickness of the support layer 130 is lower than 70 μm, it is difficult to stably support the back plate 120, and when the thickness of the support layer 130 is higher than 90 μm, the volume of the foldable display device 100 may be increased, thereby making it difficult to realize the folding ability.

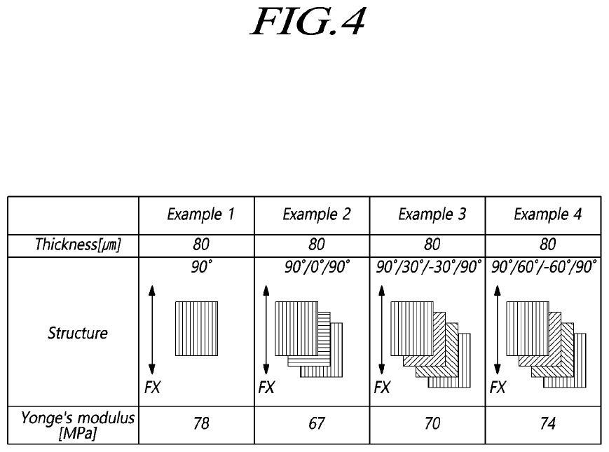

FIG. 4 is a diagram schematically illustrating examples in which the prepregs of the support layer are stacked.

Referring to FIG. 4, the support layer 130 may be formed by stacking the prepregs 130a such that the carbon fibers 32 of each prepreg 130a forming one layer may have a different orientation from the carbon fibers 32 of another prepreg 130a. Hereinafter, stacks of the prepregs 130a will be described with reference to Examples 1 to 4.

### Example 1

The support layer may include a single UD prepreg in which carbon fibers 32 are oriented in the direction of the folding axis FX, i.e., at an angle of 90° in the figures. The thickness of the UD prepreg of the support layer was 80 μm, and the tensile strength of the support layer was measured to be 78 MPa.

### Example 2

The support layer may include first UD prepregs disposed at the top and bottom positions and a second UD prepreg interposed between the first UD prepregs. The carbon fibers 32 of the first UD prepregs may be oriented in the direction of the folding axis FX, i.e., at an angle of 90° in the figures, while the carbon fibers 32 of the second UD prepreg may be oriented perpendicularly to the folding axis FX, i.e., at an angle of 0° in the figures.

The first UD prepregs and the second UD prepreg of the support layer may have the same thicknesses. In Example 2, the total thickness of the support layer was 80 μm, and the tensile strength of the support layer was measured to be 67 MPa.

### Example 3

The support layer may include first UD prepregs disposed at the top and bottom positions and second and third UD prepregs interposed between the first UD prepregs. The carbon fibers 32 of the first UD prepregs may be oriented in the direction of the folding axis FX, i.e., at an angle of 90° in the figures, the carbon fibers 32 of the second UD prepreg may be oriented at an inclination of +30° from the folding axis FX, and the carbon fibers 32 of the third UD prepreg may be oriented at an inclination of −30° from the folding axis FX.

The first to third UD prepregs of the support layer may have the same thicknesses. In Example 3, the total thickness of the support layer was 80 μm, and the tensile strength of the support layer was measured to be 70 MPa.

### Example 4

The support layer may include first UD prepregs disposed at the top and bottom positions and second and third UD prepregs interposed between the first UD prepregs. The carbon fibers 32 of the first UD prepregs may be oriented in the direction of the folding axis FX, i.e., at an angle of 90° in the figures, the carbon fibers 32 of the second UD prepreg may be oriented at an inclination of +60° from the folding axis FX, and the carbon fibers 32 of the third UD prepreg may be oriented at an inclination of −60° from the folding axis FX.

The first to third UD prepregs of the support layer may have the same thicknesses. In Example 4, the total thickness of the support layer was 80 μm, and the tensile strength of the support layer was measured to be 74 MPa.

Referring to Examples 1 to 4, when the UD prepregs of respective layers are stacked such that the carbon fibers 32 included therein have different orientations, the tensile strength of the support layer 130 may be controlled. That is, when the prepregs 130a stacked by adjusting the orientations of the carbon fibers 32, the support layers having intended physical properties may be fabricated. Accordingly, the support layer 130 customized to physical properties required for the foldable display device 100 may be provided.

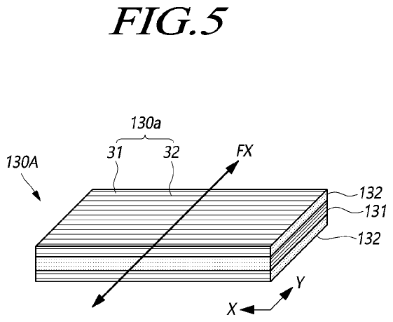

FIG. 5 is a perspective diagram illustrating a support layer according to an embodiment.

Referring to FIG. 5, a prepreg 130a of a support layer 130A may include at least one first prepreg 131 in which carbon fibers 32 are oriented in the direction of the folding axis FX and at least one second prepreg 132 in which carbon fibers 32 are oriented perpendicularly to the folding axis FX.

The orientation of the carbon fibers 32 of the prepreg 130a located at the top position of the support layer 130A and the orientation of the carbon fibers 32 of the prepreg 130a located at the bottom position of the support layer 130A may be the same. For example, two second prepregs 132 may be located at the top position and the bottom position of the support layer 130A. When the folding axis FX is in the Y-axis direction, the carbon fibers 32 of the second prepreg 132 may be oriented in the direction of the X axis. In addition, a single first prepreg 131 may be interposed between the second prepregs 132, and the carbon fibers 32 of the first prepreg 131 may be oriented in the direction of the Y axis.

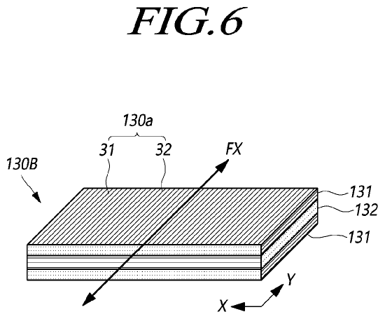

FIG. 6 is a perspective diagram illustrating a support layer according to another embodiment.

Referring to FIG. 6, a prepreg 130a of a support layer 130B may include at least one first prepreg 131 in which carbon fibers 32 are oriented in the direction of the folding axis FX and at least one second prepreg 132 in which carbon fibers 32 are oriented perpendicularly to folding axis FX.

The carbon fibers 32 included in the prepreg 130a located at the top position of the support layer 130B may be oriented in the same direction as the carbon fibers 32 included in the prepreg 130a located at the bottom position of the support layer 130B. For example, two first prepregs 131 may be located at the top and bottom positions of the support layer 130B. When the folding axis FX is in the Y-axis direction, the carbon fibers 32 of the first prepreg 131 may be oriented in the direction of the Y axis. In addition, a single second prepreg 132 may be interposed between the first prepregs 131, and the carbon fibers 32 of the second prepreg 132 may be oriented in the direction of the X axis.

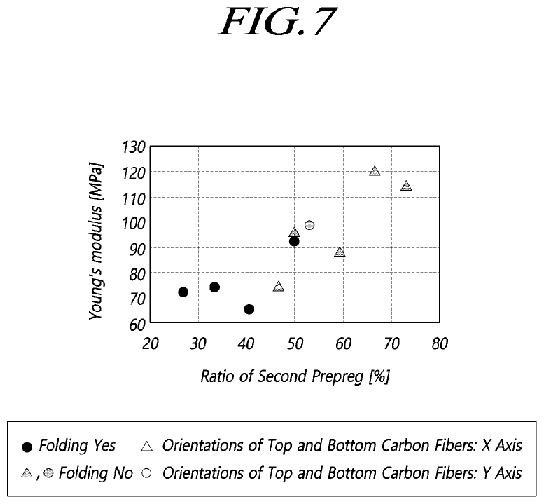

5 Table 1 below is a table showing the thickness and flatness of the support layer 130, orientations of the carbon fibers 32 included in the prepregs 130a located at the top and bottom positions, and tensile strengths and folding test results according to the ratio of the second prepreg 132. FIG. 7 is a graph illustrating the tensile strengths of the support layers and related folding test results according to the example illustrated in Table 1.

TABLE 1

| | | Orientations | | | Folding |
|---|---|---|---|---|---|
| Support | | of Top | Ratio of | | Test |
| Layer | | and Bottom | Second | Young's | (−20° C., |
| Thickness | Flatness | Carbon | Prepreg | modulus | 1 Hz, |
| (μm) | (μm) | Fibers | (%) | (GPa) | 100k) |
| 74 | 375 | X Axis | 59 | 88 | No |
| | | Y Axis | 41 | 65 | Yes |
| 94 | 776 | X Axis | 47 | 74 | No |
| | | Y Axis | 53 | 99 | No |
| 82 | 469 | X Axis | 73 | 114 | No |
| | | Y Axis | 27 | 72 | Yes |
| 90 | 563 | X Axis | 67 | 120 | No |
| | | Y Axis | 33 | 74 | Yes |
| 88 | 265 | X Axis | 50 | 95 | No |
| | | Y Axis | 50 | 92 | Yes |

Referring to Table 1 and FIG. 7, the higher the thickness of the support layer 130, the greater the tensile strength. However, when the total thickness is higher than 94 μm, it may be difficult to realize the folding. Thus, the thickness of the support layer 130 at which the folding is realizable while the back plate 120 is reliably supported may be in the range of 70 μm to 90 μm.

In addition, as illustrated in FIG. 5, when the second prepregs 132 respectively including the carbon fibers 32 oriented perpendicularly to the folding axis FX, i.e., in the direction of the X axis in the figures, are located at the top and bottom positions, the tensile strength may be increased but it may be difficult to realize the folding. In this regard, as illustrated in FIG. 6, the first prepregs 131 respectively including the carbon fibers 32 oriented in the direction of the folding axis FX, i.e., in the direction of the Y axis in the figures, may be located at the top and bottom positions.

Referring to these results, in the support layer 130 according to embodiments, the carbon fibers 32 included in the prepreg 130a located at the top position and the carbon fibers 32 included in the prepreg 130a located at the bottom position are oriented in the same direction as the folding axis FX. When the thickness of the support layer 130 including the first prepregs 131 and the second prepreg 132 is in the range of 70 μm to 90 μm, the tensile strength is excellent and the folding may be realized.

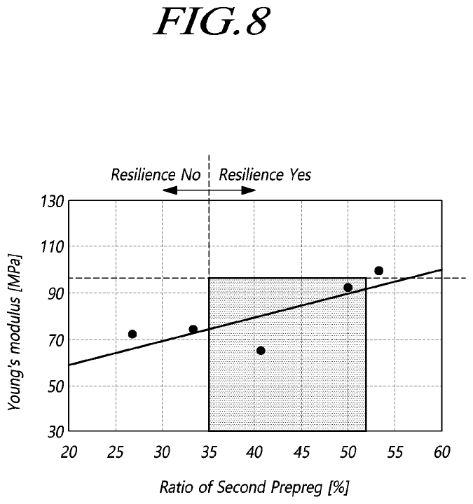

FIG. 8 is a graph illustrating tensile strength and resilience according to the ratio of the second prepreg included in the support layer illustrated in FIG. 6. Here, the term resilience means there is no lifting between respective components and thus, when the display panel 110 is unfolded after being folded, the distances of both ends from the bottom surface are limited to be less than 5 mm.

Referring to FIG. 6, the support layer 130B includes the first prepregs 131 disposed at the top and bottom positions, and the second prepreg 132 may be interposed between the first prepregs 131. In the support layer 130B having this structure, the tensile strength and resilience were measured by changing the ratio of the second prepreg 132. Specifically, at a temperature of −20° C., the foldable display device 100 was repeatedly folded at a curvature radius of 1.5R for 100,000 times by increasing the ratio of the second prepreg 132 from 20% to 60%. The result is illustrated in FIG. 8.

Referring to FIG. 8, with increases in the ratio of the second prepreg 132 including the carbon fibers 32 oriented perpendicularly to the folding axis FX in the support layer 130, the resilience increases. However, cracks may occur due to high tensile strength during the folding. Accordingly, when the support layer 130 includes the second prepreg 132 at a ratio of 35% to 52%, the support plate 130 having superior tensile strength and high resilience may be manufactured.

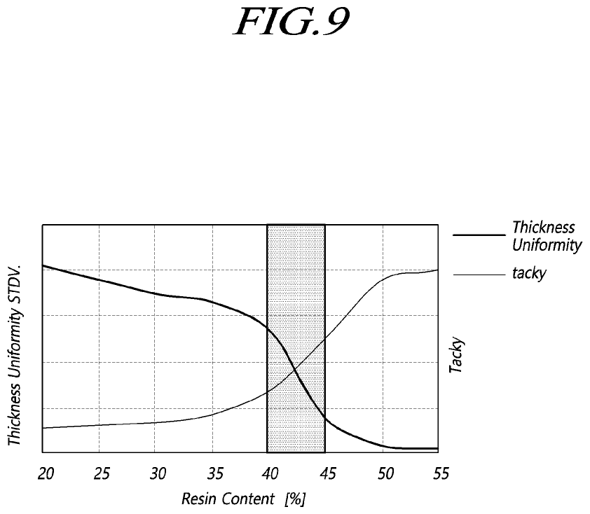

FIG. 9 is a graph illustrating the thickness uniformity and tackiness of the support layer according to the resin content in the prepreg.

Since the support layer 130 shrinks when a resin 31 therein is cured, the texture of the carbon fibers 32 may be exposed through the top and bottom surfaces. In order to overcome this problem, the resin content of the prepreg 130a may be increased.

Referring to FIG. 9, when the resin content of the prepreg 130a increases, the surface roughness due to the carbon fibers 32 was improved and thus surface flatness was advantageously improved. However, when the resin content is excessively high, stickiness may increase, thereby degrading processing performance. Accordingly, when the resin content of the prepreg 130a is set to the range of 40% to 45%, the support layer 130 having high flatness while maintaining adhesiveness may be manufactured.

When the entire resin contents of the prepregs 130a of the support layer 130 are increased, the thickness of the support layer 130 may be excessively increased. Thus, the resin contents of the prepregs 130a for respective layers may be controlled to be different. For example, the prepregs 130a located at the top and bottom positions of the support layer 130 may have a resin content of 40% to 50%, and the prepreg 130a interposed between the top and bottom prepregs 130a may have a resin content of 20% to 45%.

When the resin contents of the top and bottom prepregs 130a to be exposed to the outside are increased as above, the flatness problem due to the carbon fibers 32 in the prepreg 130a and excessive increases in the thickness of the support layer 130 due to the increased resin content may be overcome.

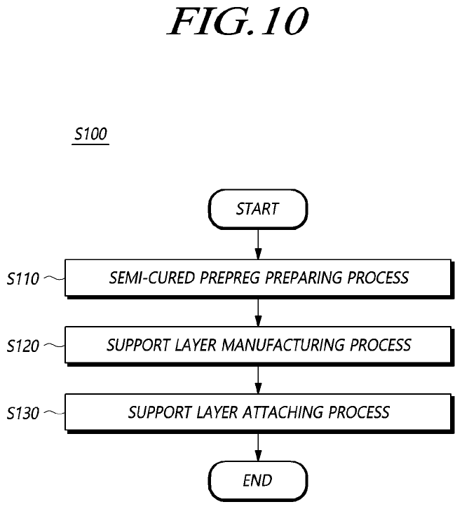

FIG. 10 is a flowchart illustrating a method of manufacturing a support plate for a foldable display device according to an embodiment. In description of the present embodiment, features of the present embodiment different from those of the foregoing embodiment will be mainly described.

Referring to FIG. 10, a method S100 of manufacturing a support plate for a foldable display device may include a semi-cured prepreg preparing process S110; a support layer manufacturing process S120; and a support layer attachment process S130.

In the semi-cured prepreg preparing operation $110, a semi-cured prepreg 130a including a resin 31 and carbon fibers 32 oriented in a single direction may be prepared. Here, the carbon fibers 32 are characterized by a low coefficient of thermal expansion (CTE), a high heat transfer rate, and a low density. When a support layer 130 is manufactured from the prepreg 130a including the carbon fibers 32, superior heat resistance and heat dissipation characteristics may be obtained, and the weight of a product may be reduced.

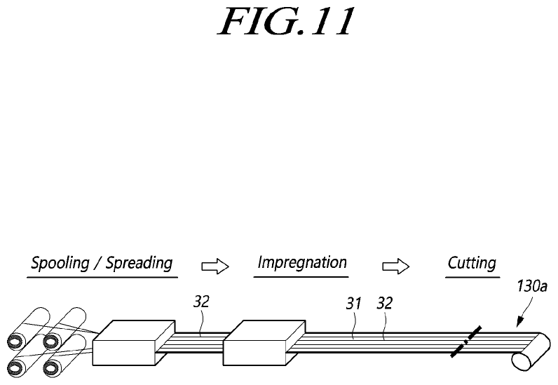

FIG. 11 is a conceptual diagram schematically illustrating a prepreg preparing process according to an embodiment.

Referring to FIG. 11, the semi-cured prepreg preparing process $110 may include: an operation of receiving a bundle of spooled carbon fibers 32 and spreading the bundle of carbon fibers 32 to be oriented in a predetermined direction; an operation of impregnating the bundle of oriented carbon fibers 32 with a resin 31; and an operation of semi-curing and then cutting the resin 31, thereby producing prepregs 130a.

As the prepregs 130a are provided in the semi-cured state as described above, when the support layer 130 is manufactured from the prepregs 130a, the support layer 130 may be provided with adhesion.

In the support layer manufacturing process S120, the support layer 130 may be manufactured by stacking one or more prepregs 130a. For example, the support layer manufacturing process S120 may include an operation of stacking at least one first prepreg 131 and at least one second prepreg 132 in an alternating manner. In the at least one first prepreg 131, the carbon fibers 32 are oriented in the direction of the folding axis FX. In the at least one second prepreg 132, the carbon fibers 32 are oriented perpendicularly to the folding axis FX. Here, the support layer 130 may include the second prepreg 132 at a ratio of 35% to 52%, and the first prepregs 131 may be disposed at the top and bottom positions of the support layer 130.

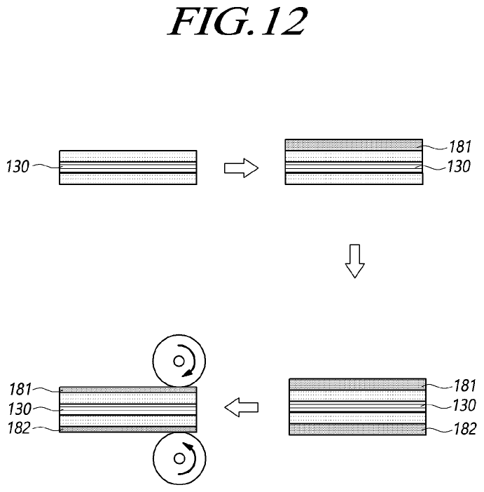

FIG. 12 is a conceptual diagram schematically illustrating a support layer manufacturing process according to an embodiment.

Referring to FIG. 12, the support layer manufacturing process S120 may include: an operation of disposing a first resin layer 181 having a predetermined thickness on the support layer 130; an operation of disposing a second resin layer 182 having a predetermined thickness below the support layer 130; and an operation of machining the surfaces of the first resin layer 181 and the second resin layer 182 by milling. Here, the first resin layer 181 and the second resin layer 182 may be formed of the same material as the resin 31 included in the support layer 130.

When the first resin layer 181 and the second resin layer 182 are prepared on and below the support layer 130, a phenomenon in which the textures of the carbon fibers 32 are exposed on the top and bottom surfaces due to the shrinking of the support layer 130 during the curing of the resin 31 may be prevented. In addition, it is also possible to prevent the thickness of the support layer 130 from being excessively high when the surface machining is performed by the milling.

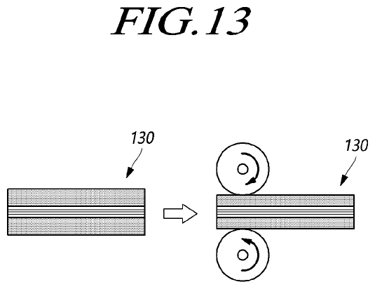

FIG. 13 is a conceptual diagram schematically illustrating a support layer manufacturing process according to another embodiment.

Referring to FIG. 13, the support layer manufacturing process $120 may include an operation of machining the surfaces of the prepregs 130a located at the top and bottom positions of the support layer 130 by milling. Here, each of the prepregs 130a located at the top and bottom positions of the support layer 130 may include a resin content of 40% to 45%, and the prepreg 130a interposed between the prepregs 130a located at the top and bottom positions of the support layer 130 may include a resin content of 20% to 45%.

That is, when the resin content of each of the prepregs 130a located at the top and bottom positions of the support layer 130 exposed to the outside is set to be higher than the resin content of the prepreg 130a interposed therebetween, the texture of the carbon fibers 32 may be prevented from being exposed from the surface of the support layer 130.

In the support layer attachment process S130, the support layer 130 may be attached to the bottom portion of the back plate 120 foldable about the folding axis FX. That is, the support layer 130 may be supported while being attached to the back plate 120, and may be attached to the back plate 120 using the adhesiveness thereof without a separate adhesive.

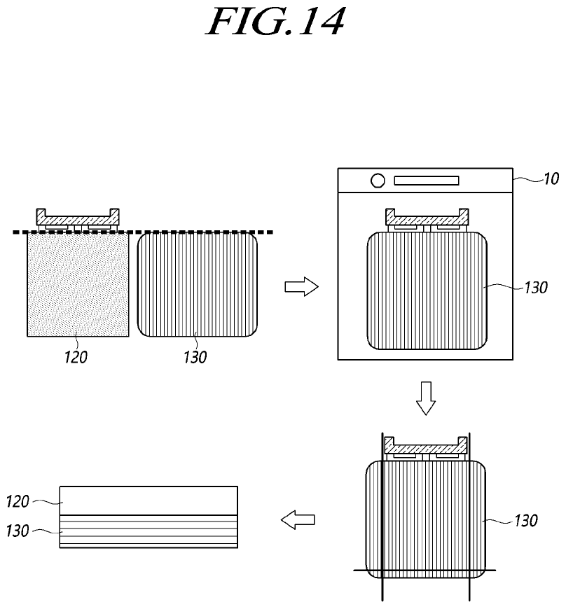

FIG. 14 is a conceptual diagram schematically illustrating a support layer attachment process according to an embodiment.

Referring to FIG. 14, the support layer attachment process $130 may include: an operation of attaching the semi-cured support layer 130 to the back plate 120; an operation of curing the support layer 130 at a predetermined temperature and a predetermined pressure within an autoclave 10; and an operation of removing peripheral portions of the support layer 130 by trimming. Through this process, the support layer 130 may be attached to the bottom portion of the back plate 120 without an adhesion layer.

The above-described embodiments of the present disclosure will be briefly reviewed as follows.

Embodiments may provide a support plate for a foldable display device. The support plate may be provided on a bottom portion of a back plate bendable about a folding axis. The support plate may include a support layer. The support layer may include one or more prepregs each including a resin and carbon fibers. The support plate may have a semi-cured state when being attached to the bottom portion of the back plate.

According to embodiments, the resin may comprise a thermosetting resin.

According to embodiments, the carbon fibers included in each of the prepregs may be oriented in a single direction.

According to embodiments, the thickness of the support layer may range from 70 μm to 90 μm.

According to embodiments, the support layer may comprise a resin content of 40% to 45%.

According to embodiments, the support layer may further include a resin layer disposed on at least one of an upper surface and a lower surface of the support layer.

According to embodiments, the support layer may include a single prepreg, and the carbon fibers included in the single prepreg may be oriented in a direction of the folding axis.

According to embodiments, the support layer may include at least one first prepreg and at least one second prepreg stacked on each other in a top-bottom direction.

According to embodiments, the carbon fibers included in the first prepreg may have a different orientation from the carbon fibers included in the second prepreg.

According to embodiments, the first prepreg may be located at a top position and a bottom position of the support layer.

According to embodiments, the carbon fibers included in the first prepreg may be oriented in the direction of the folding axis.

According to embodiments, a resin content of the first prepreg may be greater than a resin content of the second prepreg.

According to embodiments, the first prepreg may include a resin content of 40% to 50%. The second prepreg may include a resin content of 20% to 45%.

According to embodiments, the carbon fibers included in the second prepreg are oriented perpendicularly to the folding axis.

According to embodiments, the support layer may include the second prepreg at a ratio of 35% to 52%.

According to embodiments, the support plate may exclude an open area pattern.

Embodiments may provide a method of manufacturing a support plate for a foldable display device. The method may include: preparing a semi-cured prepreg including a resin and carbon fibers oriented in a single direction; and manufacturing a support layer by stacking one or more prepregs.

According to embodiments, the preparation of the semi-cured prepreg may include: receiving a bundle of spooled carbon fibers and spreading the bundle of carbon fibers to be oriented in a predetermined direction; impregnating the bundle of oriented carbon fibers with a resin; and semi-curing and then cutting the resin, thereby producing the prepregs.

According to embodiments, the manufacturing of the support layer may include stacking at least one first prepreg and at least one second prepreg. The carbon fibers in the first prepreg may be oriented in the direction of a folding axis, and the carbon fibers in the second prepreg may be oriented perpendicularly to the folding axis.

According to embodiments, the support layer may include the second prepreg at a ratio of 35% to 52%.

According to embodiments, the first prepregs may be disposed at a top position and a bottom position of the support layer.

According to embodiments, the manufacturing of the support layer may include: disposing a first resin layer having a predetermined thickness on the support layer; disposing a second resin layer having a predetermined thickness below the support layer; and machining surfaces of the first resin layer and the second resin layer by milling.

According to embodiments, each of the prepreg located at a top position of the support layer and the prepreg located at a bottom position of the support layer may include a resin content of 40% to 50%, and the prepreg interposed between the prepreg located at the top position of the support layer and the prepreg located at the bottom position of the support layer may include a resin content of 20% to 45%.

According to embodiments, the manufacturing of the support layer may include machining surfaces of the prepreg located at the top position of the support layer and the prepreg located at the bottom position of the support layer by milling.

According to embodiments, the method may further include attaching the support layer to a bottom portion of the back plate foldable about a folding axis. The attachment of the support layer may include: attaching the semi-cured support layer to the back plate; curing the support layer; and removing peripheral portions of the support layer by trimming.

Embodiments may provide a foldable display device including: a display panel including a folding area and a non-folding area; a back plate supporting a bottom portion of the display panel; and a support plate supporting a bottom portion of the back plate and including one or more prepregs each including a resin and carbon fibers. The support plate may have a semi-cured state when being attached to the bottom portion of the back plate.

The above description has been presented to enable any person skilled in the art to make and use the technical idea of the present invention, and has been provided in the context of a particular application and its requirements. Various modifications, additions and substitutions to the described embodiments will be readily apparent to those skilled in the art, and the general principles defined herein may be applied to other embodiments and applications without departing from the spirit and scope of the present invention. The above description and the accompanying drawings provide an example of the technical idea of the present invention for illustrative purposes only. That is, the disclosed embodiments are intended to illustrate the scope of the technical idea of the present invention.

What is claimed is:

1. A support plate for a foldable display device, the support plate provided on a bottom portion of a back plate bendable about a folding axis, the support plate comprising:
a support layer comprising one or more prepregs each comprising a resin and carbon fibers,
wherein the support plate has a semi-cured state when being attached to the bottom portion of the back plate.

2. The support plate according to claim 1, wherein the resin comprises a thermosetting resin.

3. The support plate according to claim 1, wherein the carbon fibers included in each of the prepregs are oriented in a single direction.

4. The support plate according to claim 1, wherein a thickness of the support layer ranges from 70 μm to 90 μm.

5. The support plate according to claim 1, wherein the support layer comprises a resin content of 40% to 45%.

6. The support plate according to claim 1, further comprising:
a resin layer disposed on at least one of an upper surface and a lower surface of the support layer.

7. The support plate according to claim 1, wherein the support layer comprises a single prepreg, and the carbon fibers included in the single prepreg are oriented in a direction of the folding axis.

8. The support plate according to claim 1, wherein the support layer comprises at least one first prepreg and at least one second prepreg stacked on each other in a top-bottom direction, and
the carbon fibers included in the first prepreg have a different orientation from the carbon fibers included in the second prepreg.

9. The support plate according to claim 8, wherein the first prepregs are located at a top position and a bottom position of the support layer.

10. The support plate according to claim 8, wherein the carbon fibers included in the first prepreg are oriented in a direction of the folding axis.

11. The support plate according to claim 9, wherein a resin content of the first prepreg is greater than a resin content of the second prepreg.

12. The support plate according to claim 11, wherein the first prepreg comprises a resin content of 40% to 50%, and
the second prepreg comprises a resin content of 20% to 45%.

13. The support plate according to claim 10, wherein the carbon fibers included in the second prepreg are oriented perpendicularly to the folding axis.

14. The support plate according to claim 13, wherein the support layer comprises the second prepreg at a ratio of 35% to 52%.

15. The support plate according to claim 1, wherein the support plate excludes an open area pattern.

16. A method of manufacturing a support plate for a foldable display device, the method comprising:
preparing a semi-cured prepreg comprising a resin and carbon fibers oriented in a single direction; and
manufacturing a support layer by stacking one or more prepregs.

17. The method according to claim 16, wherein the preparation of the semi-cured prepreg comprises:
receiving a bundle of spooled carbon fibers and spreading the bundle of carbon fibers to be oriented in a predetermined direction;
impregnating the bundle of oriented carbon fibers with a resin; and
semi-curing and then cutting the resin, thereby producing the prepregs.

18. The method according to claim 16, wherein the manufacturing of the support layer comprises stacking at least one first prepreg and at least one second prepreg,
wherein the carbon fibers in the first prepreg are oriented in a direction of a folding axis, and the carbon fibers in the second prepreg are oriented perpendicularly to the folding axis.

19. The method according to claim 18, wherein the support layer comprises the second prepreg at a ratio of 35% to 52%.

20. The method according to claim 18, wherein the first prepregs are disposed at a top position and a bottom position of the support layer.

21. The method according to claim 16, wherein the manufacturing of the support layer comprises:
disposing a first resin layer having a first predetermined thickness on the support layer;
disposing a second resin layer having a second predetermined thickness below the support layer; and
machining surfaces of the first resin layer and the second resin layer by milling.

22. The method according to claim 16, wherein each of the prepreg located at a top position of the support layer and the prepreg located at a bottom position of the support layer comprises a resin content of 40% to 50%, and
the prepreg interposed between the prepreg located at the top position of the support layer and the prepreg located at the bottom position of the support layer comprises a resin content of 20% to 45%.

23. The method according to claim 22, wherein the manufacturing of the support layer comprises machining surfaces of the prepreg located at the top position of the support layer and the prepreg located at the bottom position of the support layer by milling.

24. The method according to claim 16, further comprising attaching the support layer to a bottom portion of a back plate foldable about a folding axis,
wherein the attachment of the support layer comprises:
attaching the semi-cured support layer to the back plate;
curing the support layer; and
removing peripheral portions of the support layer by trimming.

25. A foldable display device, comprising:
a display panel comprising a folding area and a non-folding area;
a back plate supporting a bottom portion of the display panel; and
a support plate supporting a bottom portion of the back plate, and comprising one or more prepregs each comprising a resin and carbon fibers,
wherein the support plate has a semi-cured state when being attached to the bottom portion of the back plate.
